(19) United States
(12) Patent Application Publication
(10) Pub. No.: US 2013/0134476 A1
(43) Pub. Date: May 30, 2013

(54) SOLID-STATE DIODE

(71) Applicant: Jan Degenhardt, Dortmund (DE)

(72) Inventor: Jan Degenhardt, Dortmund (DE)

(73) Assignee: ELMOS SEMICONDUCTOR AG, Dortmund (DE)

(21) Appl. No.: 13/547,833

(22) Filed: Jul. 12, 2012

(30) Foreign Application Priority Data
Jul. 19, 2011 (EP) 11174540.2

(51) Int. Cl. H01L 29/866

(52) U.S. Cl. CPC H01L 29/866
USPC 257/106

(57) ABSTRACT

The solid-state diode comprises a semiconductor substrate having a top side and having two masking regions formed on the top side of the semiconductor substrate and made of a first masking material impermeable to ion implantation, the masking regions comprising two mutually opposite limiting edge portions. The solid-state diode comprises an n-doped cathode region formed in the semiconductor substrate and extending up into the intermediate region between the mutually opposite limiting edge portions of the masking regions, the n-doped cathode region comprising a cathode connection field. The diode comprises a p-doped anode region formed in the semiconductor substrate, extending up into the intermediate region between the mutually opposite limiting edge portions of the masking regions and bordering/overlapping on the cathode region, the p-doped anode region comprising an anode connection field. The masking regions and either the cathode or the anode connection field are substantially on the same electric potential.

### RELATED CROSS-REFERENCING

The present invention claims the priority of European Patent Application No. 11 174 540.2, filed on Jul. 19, 2011, the disclosure of which is incorporated herein by reference.

### BACKGROUND OF THE INVENTION

1. Field of the Invention

The present invention relates to a solid-state diode, i.e. a semiconductor electrode comprising a p-n transition, which can be used particularly for voltage stabilization in electric circuits. Preferably, the solid-state diode is a Zener diode, while the invention is not restricted to such diode types. The diode design according to the invention is however generally unsuited for application in zapping diodes.

2. Description of the Prior Art

The functionality of semiconductor and respectively solid-state diodes can be based on a punch, bipolar or Zener breakdown, wherein the Zener breakdown combines two breakdown mechanisms with each other, namely a tunnel breakdown and an avalanche breakdown. These two last-mentioned mechanisms have opposite temperature coefficients so that a Zener diode can be designed in such a manner that the temperature coefficient and respectively the temperature dependency at the operating point will vanish, so-to-speak. For this reason, Zener diodes are suitable e.g. for voltage stabilization. In other applications for Zener diodes, these diodes are used as protective structures against overvoltage in circuits. In such a case, a Zener diode will mostly control a power transistor which will then reduce the overvoltage. In the process, the diode shall burden the to-be-protected signal path only with a small leakage current until the state of protecting the signal path has been reached. Further, not only a Zener diode but diodes in general are subject to the requirement that the spread of the amount of the breakdown voltage as caused by the production process should be kept as small as possible.

A diode comprises one or a plurality of serially connected p-n transitions, i.e. mutually adjacent n-doped cathode and p-doped anode regions in a semiconductor substrate. In case of a breakdown, a current flow will take place which, in a Zener diode, is composed of a tunnel current and an avalanche current, as already briefly mentioned above. Parallel to the “main current” in the breakdown case, parasitic currents will occur, flowing around the region of the breakdown. This is caused by the effect that, in conventional diode designs, the p- and n-regions are bordering each other across a relatively large width. In such an arrangement, the position of the breakdown is not predictable and, along the width extension, may generally lie at any random site. Primarily, the breakdown will occur where the space charge zone has its smallest depth, i.e. its smallest extension in the current flow direction. Due to production conditions, notably, the depth of the space charge zone along the width of the p-n transition is not constant but varying.

In WO-A-95/17013, a drift-free avalanche-type breakdown diode is described.

It is already known to keep the width of a p-n transition of a solid-state diode relatively small in order to limit the region of the breakdown. Examples of such solid-state diodes are described in DE-C-197 23 747 and WO-A-03/054971. The beveled opposing peaks of the n- and p-doped regions described in the latter document are also provided in the diode design according to DE-C-197 23 747. However, the two diode designs according to the above mentioned documents may still suffer from parasitic effects, with a resultant loss in functional reliability. Further, it is to be noted that DE-C-197 23 747 describes a zapping diode whose use is directed to an irreversible breakdown so that, for this reason, a high current capability is undesired.

It is an object of the invention to provide a solid-state diode which, with respect to its functionality, is capable of working in a more reliable manner.

### SUMMARY OF THE INVENTION

To achieve the above object, there is provided, in accordance with the invention, a solid-state diode comprising
a semiconductor substrate having a top side,
two masking regions formed on the top side of the semiconductor substrate and made of a first masking material impermeable to ion implantation, said masking regions comprising two mutually opposite limiting edge portions,
an n-doped cathode region formed in the semiconductor substrate and extending up into the intermediate region between said mutually opposite limiting edge portions of the masking regions, said n-doped cathode region comprising a cathode connection field, and
a p-doped anode region formed in the semiconductor substrate and extending up into the intermediate region between said mutually opposite limiting edge portions of the masking regions and bordering on the cathode region and/or overlapping the same, said p-doped anode region comprising an anode connection field.

In this solid-state diode, it is provided, according to the invention,
that the masking regions and either the cathode connection field or the anode connection field are substantially on the same electric potential, i.e. are either directly or indirectly electrically connected/coupled to each other.

Before proceeding with the detailed description of the invention, it should be mentioned quite generally that the diode of the invention can normally be embedded in a well structure (the so-called body) formed in a (semiconductor) substrate and consisting of an n-well and a p-well within an n-well, so that the operation of the diode can be performed above or below the substrate potential (the substrate being e.g. of the p-type). The term “semiconductor substrate” in the following text has to be understood in correspondence to this.

In the solid-state diode of the invention, the two cathode and anode regions forming a p-n transition are formed and oriented to be self-adjusting, which is effected by means of said two mutually opposite masking regions with their mutually spaced and mutually opposite limiting edge portions. In the region between these two masking regions, there is formed the actual p-n transition via which the breakdown current will flow. Outside the masking regions, the cathode and anode regions can be designed with a larger width than inside the masking region.

In the invention, the p-n transitions of diodes are conventionally formed in doped well regions of semiconductor substrates. These semiconductor substrates are (weakly) p- or n-doped. The actual cathode and anode regions are heavily n- and respectively p-doped and thus are higher-doped than the semiconductor substrate. This integration of the p-n transition of the well regions allows for operation of the diode above or below the potential of the semiconductor substrate.

By the spacing of the n- and p-doped cathode and anode regions of the solid-state diode of the invention outside the region between the two masking regions, notably where the two cathode and anode regions are—in the flow direction—spaced from each other by the dimension of the masking regions, the so-called GIDL effect (gate-induced drain leakage) may come to happen. In a p-semiconductor substrate, this effect will occur at the transition of the cathode region, and, in an n-semiconductor substrate, at the transition of the anode region to the semiconductor substrate, each time below the masking region. However, since the invention provides that the cathode connection field (or alternatively the anode connection field) is at the same electric potential as the masking regions, said GIDL effect is counteracted below the masking regions. By the application of potentials according to the invention, the potential of the masking regions follows that of the cathode region and respectively of the anode region, depending on whether the masking region is electrically connected to the cathode region or to the anode region, and thus generates an inversion channel on the surface of the semiconductor substrate below the masking region. By this application of potentials, a parasitic MIS (metal insulator semiconductor) capacitor is formed.

The solid-state diode of the invention, due to its constricted p-n transition and its cathode and anode regions which are oriented for self-adjustment (notably where the breakdown current is generated), and due to its application of potentials—in that the cathode connection field or alternatively the anode connection field is at the same electric potential as the masking regions—guarantees a reliable and reproducible functionality and thus under the aspect of circuit technology has advantageous properties which are beneficial particularly when using the solid-state diode for voltage stabilization and voltage limitation, which cannot be achieved by a Zener diode of the type described in DE-C-197 23 747.

According to an advantageous further embodiment of the invention, it is provided that the n-doped cathode region is generated by an ion implantation, wherein the ions of this implantation have a relatively small mobility within the semiconductor substrate so that the implanted region will hardly expand under the effect of the normally occurring thermal diffusion. For the p-doped anode region, by contrast, a doping material is used which has a relatively high mobility within the semiconductor substrate. Accordingly, in a situation of thermal diffusion, the implanted p-doped anode region will expand distinctly more than the n-doped cathode region. Thus, after the n-doped ion implantation and prior to the p-doped ion implantation, a masking edge strip (comparable to a so-called spacer at the polysilicon gate of a transistor) will be deposited at least along the mutually facing limiting edge portions of the two masking regions, so that the p-ion implantation will generate, adjacent to the n-doped cathode region, a centered p-doped region in the semiconductor substrate, with the width of said p-doped region being smaller than that of the n-doped cathode region by the width of the opposite masking edge strips. In the subsequent thermal treatment of the semiconductor substrate, the p-doped region will expand up to the region below the masking edge strip, thus becoming wider and thereby reaching substantially the width of the n-doped region.

The first masking material suitably is polycrystalline silicon which optionally can be silicidized. The second masking material, also referred to as a “spacer” in the semiconductor component industry, is suitably silicon nitride.

### BRIEF DESCRIPTION OF THE DRAWINGS

A full and enabling disclosure of the present invention, including the best mode thereof, enabling one of ordinary skill in the art to carry out the invention, is set forth in greater detail in the following description, including reference to the accompanying drawing in which

FIGS. 1 to 10 are plan views of a semiconductor substrate and special sectional views of the semiconductor substrate in the various phases of the manufacturing process of an embodiment of a diode,

FIG. 11 is a sectional view for illustration of the GIDL effect, and

FIG. 12 is an equivalent circuit diagram of a diode.

### DETAILED DESCRIPTION OF PREFERRED EMBODIMENTS

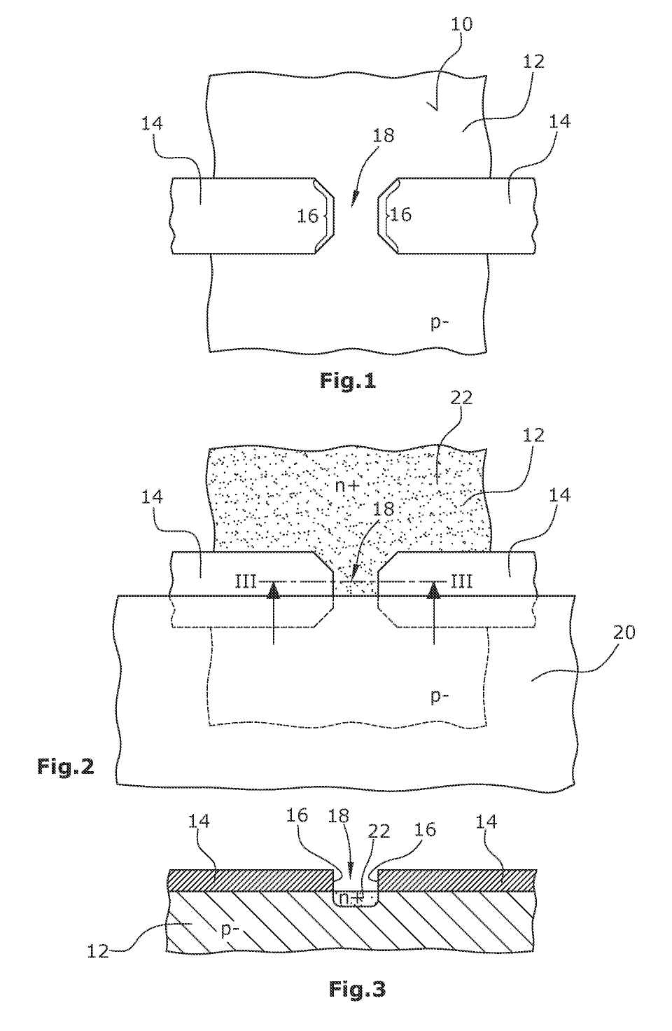

FIG. 1 illustrates, in plan view, a portion of the top side 10 of a weakly p-doped well region of a silicon semiconductor substrate 12 on which two masking regions 14 of polycrystalline silicon are formed that, in the present embodiment, are respectively strip-shaped. The two masking regions 14 comprise mutually facing limiting edge portions 16 which are spaced from each other and delimit a constriction region and respectively intermediate region 18 on two opposite sides. In said intermediate region 18, the p-n transition of the to-be-produced solid-state diode will be generated, which will be described in greater detail with reference to the further Figures.

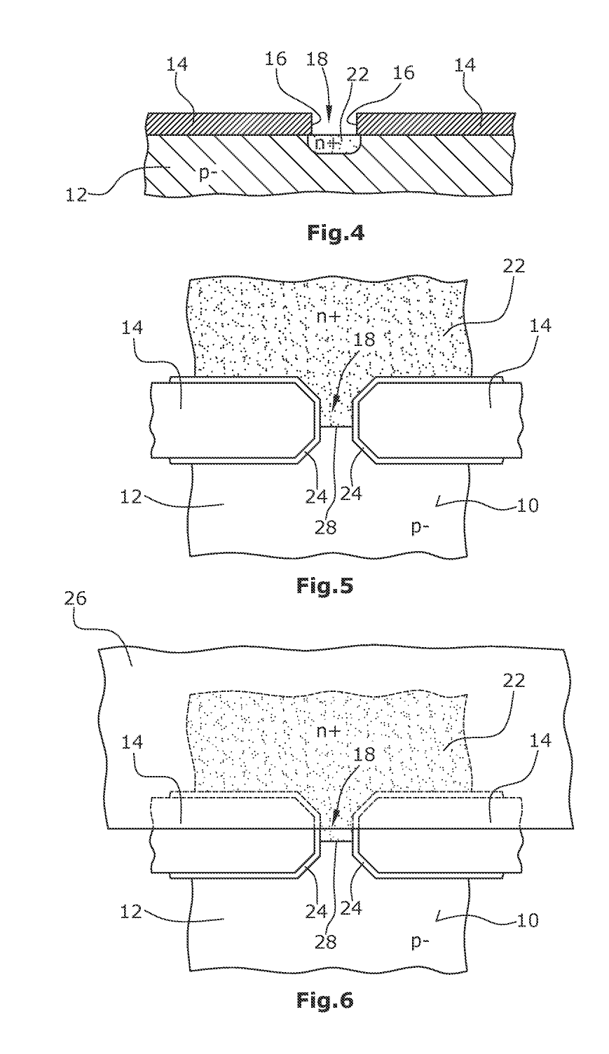

As shown in FIG. 2, that portion of the top side 10 of the semiconductor substrate 12 which in the view of FIG. 2 is situated below the masking regions 14, will be covered by a mask 20 impermeable to an ion implantation, wherein said mask 20 projects all the way into the above mentioned intermediate region 18 and also extends along a part of the masking regions 14. Now, an ion implantation is performed for generating the n-conducting cathode region 22. The profile of the cathode region 22 in the area of said intermediate region 18 after ion implantation is shown in the cross-sectional view of FIG. 3. In order to “heal” the crystal lattice disturbances in the implanted cathode region 22, a thermal treatment step is performed which results in thermal diffusion. The n-conducting doping material is provided e.g. in the form of arsenic atoms which due to their size have only a relatively restricted mobility within the silicon. Thus, the doped cathode region 22 will expand only slightly, as shown in cross section in FIG. 4.

In the next production step, as shown in FIG. 5, a respective masking edge strip 24 will be deposited along the edges of the masking regions 14. The production methods for this step are generally known from the manufacture of so-called spacers (made e.g. from silicon nitride) in polysilicon gates of transistors and thus will not be described in greater detail here.

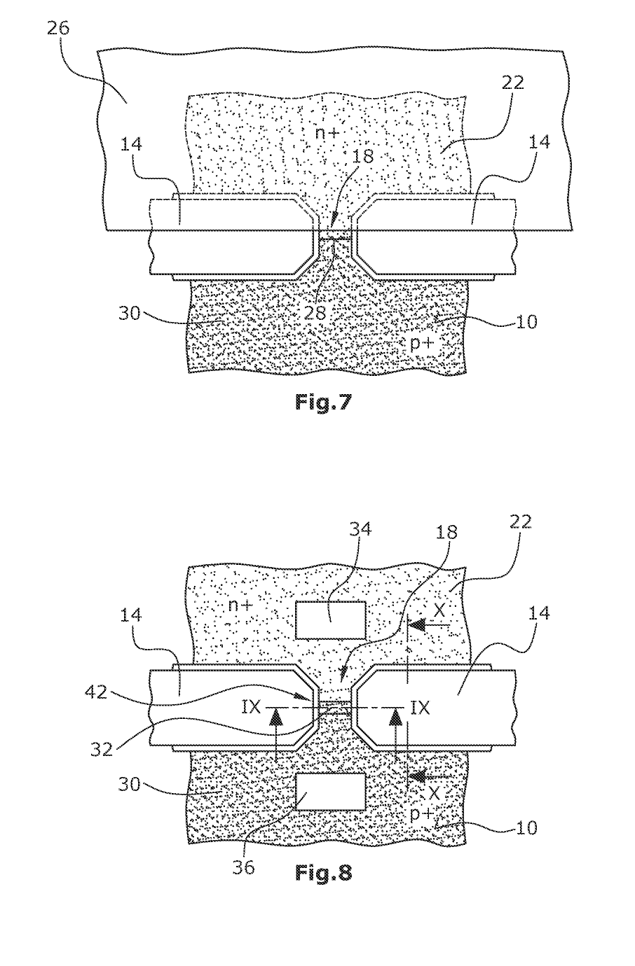

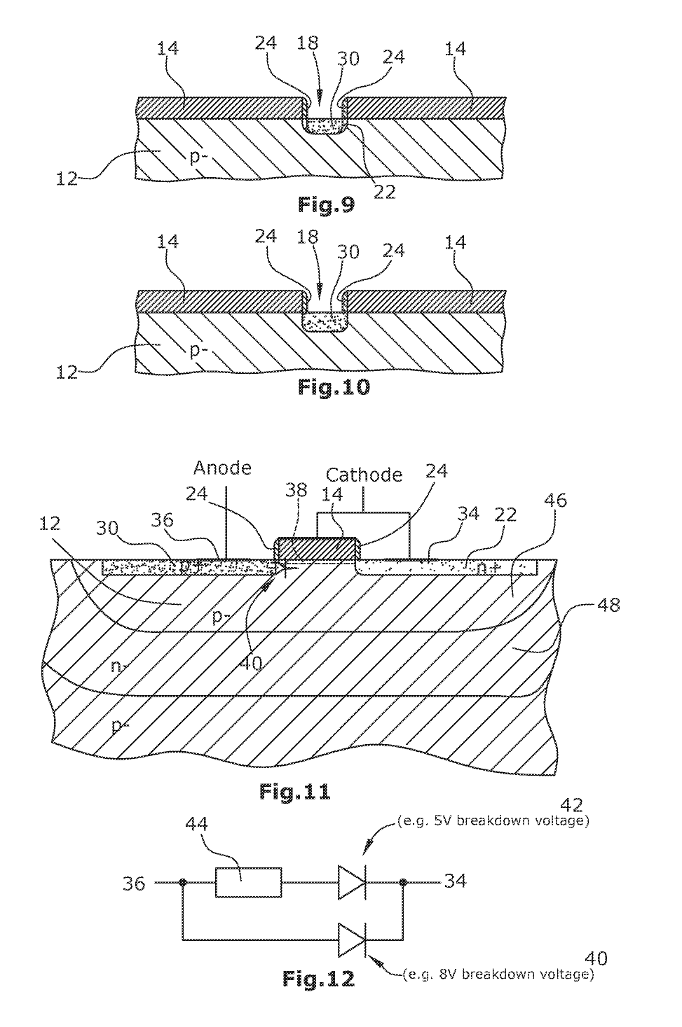

In FIG. 6, it is shown that the already implanted cathode region 22 is covered by a mask 26 which within the intermediate region 18 is only slightly set back relative to the boundary 28 of cathode region 22. After this mask 26 has been formed, an ion implantation is performed by use of a p-doping material (e.g. boron) so as to generate the anode region 30 (see FIG. 7). From FIGS. 7 and 8, it can be seen that the cathode and anode regions 22,30 overlap each other in the area of the intermediate region 18 (see reference numeral 32). Also shown in FIG. 8 are a cathode connection field 34 and an anode connection field 36. The profile of the n- and p-conducting doping materials in the intermediate region 18 after implantation is shown in FIG. 9. To be seen is the less wide extension of the implanted p-region 30 in lateral direction, said lesser width being caused the spacer masking edge strips 24. During the subsequent thermal “healing” of the crystal lattice structure in the silicon of the semiconductor substrate 12, the anode region 30 will laterally expand and will reach all the way to a site under the spacer masking edge strips 24, thus having substantially the same lateral extension as the cathode region 22 (see FIG. 10).

With reference to FIG. 11, a further special feature of the solid-state diode of the invention will be discussed hereunder. As can be seen, the extension of the masking regions 14 in the direction of the current flow through the diode has the effect that the cathode and anode regions 22,30 of the diode are spaced from each other outside the masking regions 22. Since the cathode region 22 and the masking regions 14 of polycrystalline silicon are at the same potential (see, in FIG. 11, the electrical connection between these regions), there is advantageously avoided the so-called GIDL effect (gate-induced drain leakage) at the transition of the cathode region 22 to the weakly p-doped silicon semiconductor substrate 12 below the masking regions 14. The potential of the masking regions 14 will thus follow that of the cathode region 22 and will generate an inversion channel 38 on the surface of the weakly p-doped silicon semiconductor substrate 12 below the masking regions 14. Through said inversion channel 38, charges will flow from the cathode region 22 to the anode region 30. At the transition from inversion channel 38 to anode region 30, a parasitic p-n transition (diode 40) is generated.

The GIDL effect, as mentioned and briefly outlined above, is of a two-fold advantageous importance for the invention, notably, on the one hand, with respect to its suppression on the cathode side and, on the other hand, with respect to its beneficial effect on the anode side, i.e. the diode shown as an example in the Figures. Both aspects shall once again be explained in greater detail hereunder.

For clarification of terms, it should first be noted that the bipolar transition between the inverted channel 38 and the p-anode region 30 is referred to as a parasitic diode 40. The diode determining the Zener effect, formed by the p-n transition in said intermediate region 18, is to be called a “primary diode” 42. The diode can be embedded into a well structure (body) consisting of an n-well or a p-within-n well 46,48 (see FIG. 11) so that the operation of the diode can take place above or below the substrate potential (the substrate herein being of the p-type). For special applications, however, the insulating n-well can be omitted, and the p-body will then correspond to the p-substrate; a comparable arrangement will be provided in the reverse case (n-body in an n-substrate). Thus, the term “semicondoctor substrate” in its narrower sense pertains only to the exemplary case of a p-body without n-well in the p-substrate.

The functionality of the diode of the invention can be altered by applying different potentials to the masking region 14. The masking region 14 can be electrically connected to the cathode region 22 or the anode region 30. Apart therefrom, the diode of the invention can be formed by a p-body or an n-body. If one concentrates on the two variants of the body and the two variants of contacting, this will result in four possible constellations. Hereunder, there will be discussed, by way of example, the configuration of the diode with p-body—without insulating well, therefore equivalent to the p-substrate—and the electrical connection of the cathode region 22 and the masking region 14.

If the semiconductor substrate is provided with a p-type net doting and if the cathode region 22 is connected to the masking region 14, operation of the diode in the reverse direction will entail an inversion of the band assignment below the masking region 14. The cathode region 22 (n-doted) is then conductively connected to the generated n-conducting (inversion) channel 38. The previously existing lateral p-n transition—not shown in FIG. 11—between the near-surface p-substrate layer below the masking region 14 and the cathode region 22 has been eliminated by the generation of the inversion channel 38, and the GIDL effect will thus become insubstantial at this site of the construction.

On the opposite side of the masking region 14 when viewed in the longitudinal direction, the inversion channel region is in abutment on the p-doting of the anode region 30. This (n-channel) (p⁺⁺) transition, as compared to the p-n transition of the primary diode 42, has a larger space charge zone, which is a result of the smaller band bending effect by the inversion channel as a (p⁺⁺) antipole. The breakdown voltage is generally far above the breakdown voltage of the primary diode. Thus, the diode of the invention consists of two parallel-connected diode paths, i.e. the primary diode 42 which will proceed to breakdown in case of smaller voltages (e.g. 5 V), and the parasitic diode which will proceed to breakdown in case of higher voltages (e.g. 8V).

The corresponding equivalent circuit diagram is shown in FIG. 12. This blocked parasitic diode 40, if it were without the positive potential of the cathode region 22 (the diode is operated “reversely”) which is also applied to the masking region 14, would remain inactive in the functional range of the primary diode 42.

The masking region 14, which due to the electrical connection with the cathode connection field 34 is electrically negatively charged, will initiate a weakening of said blocked parasitic diode 40 (GIRL effect). Thereby, the breakdown voltage of the parasitic diode 40 is shifted toward smaller values. In case of suitable selection of the design of the diode of the invention, the breakdown voltage of the parasitic diode 40 is (slightly) above the breakdown voltage of the primary diode 42.

The intermediate region 18 and its doping constitute an electric resistor 44 (see FIG. 12) which will limit the current via the primary diode 42. With increasing strength of the current, this feed resistor will become dominant in the current/voltage characteristic of the primary diode 42, i.e. will approximate a linear behavior, thus reducing the influence of the primary diode 42. From a certain voltage, the GIDL effect will cause a leakage of the parasitic diode 40 which with rising voltage will lead increasingly more current past the primary diode 42. Since the parasitic diode 40 extends toward the anode region 30 along the whole edge of the masking region 14 and thus occupies the width of almost the entire masking region (semiconductor substrate), this parasitic diode 40 is able to conduct a very large current.

In case of small voltages applied to the diode of the invention, the above mechanism will provide for a small leakage current. For voltages above the breakdown voltage of the primary diode 42, the parasitic diode 40 will be activated via the GIRL effect and contribute to current transport. Thus, the diode of the invention comprises a highly effective internal protective mechanism against current peaks, but also comprises a precise breakdown site with high voltage stability, and thus has two properties which are definitively not desirable in a zapping diode forming the subject matter of DE-C-197 23 747.

Although the invention has been described and illustrated with reference to specific illustrative embodiments thereof, it is not intended that the invention be limited to those illustrative embodiments. Those skilled in the art will recognize that variations and modifications can be made without departing from the true scope of the invention as defined by the claims that follow. It is therefore intended to include within the invention all such variations and modifications as fall within the scope of the appended claims and equivalents thereof.

1. A solid-state diode comprising
a semiconductor substrate having a top side,
two masking regions formed on the top side of the semiconductor substrate and made of a first masking material impermeable to ion implantation, the masking regions comprising two mutually opposite limiting edge portions,
an n-doped cathode region formed in the semiconductor substrate and extending up into the intermediate region between the mutually opposite limiting edge portions of the masking regions, the n-doped cathode region comprising a cathode connection field, and
a p-doped anode region formed in the semiconductor substrate and extending up into the intermediate region between the mutually opposite limiting edge portions of the masking regions and bordering on the cathode region and/or overlapping the same, the p-doped anode region comprising an anode connection field, wherein
the masking regions and either the cathode connection field or the anode connection field are substantially on the same electric potential.

2. The solid-state diode of claim 1, wherein an edge strip of a second masking material impermeable to ion implantation is formed at least along each of the mutually facing limiting edge portions of the two masking regions.

3. The solid-state diode of claim 1, wherein the first masking material is electrically conducting and comprises a polycrystalline, and wherein the second masking material is silicon oxide or silicon nitride.

4. The solid-state diode of claim 3, wherein the first masking material comprises silicadized silicon.
